(19) United States
(12) Patent Application Publication
(10) Pub. No.: US 2025/0253239 A1
(43) Pub. Date: Aug. 7, 2025

(54) SEMICONDUCTOR DEVICE AND METHOD FOR FABRICATING THE SAME

(71) Applicant: SK hynix Inc., Icheon-si (KR)

(72) Inventor: Jeong Hwan SONG, Icheon-si (KR)

(21) Appl. No.: 18/645,288

(22) Filed: Apr. 24, 2024

(30) Foreign Application Priority Data
Feb. 7, 2024 (KR) 10-2024-0018785

(51) Int. Cl. H01L 23/528; H10B 61/00; H10N 50/01; H10N 50/10

(52) U.S. Cl. CPC H01L 23/5283; H10B 61/00; H10N 50/01; H10N 50/10

(57) ABSTRACT

A semiconductor device and a method for fabricating the same may be provided. The semiconductor device may include a plurality of first conductive lines extending in a first direction; a plurality of second conductive lines disposed separately from and over the plurality of first conductive lines and extending in a second direction intersecting the first direction; and a plurality of memory cells overlapping intersection areas between the first conductive lines and the second conductive lines, respectively. The plurality of memory cells may include a plurality of first memory cells each including a first memory pattern and a first selector pattern and a plurality of second memory cells each including a second selector pattern and a second memory pattern, and in each of the first direction and the second direction, one or more of the first memory cells and one or more of the second memory cells may be alternately arranged.

### PRIORITY CLAIM AND CROSS-REFERENCE TO RELATED APPLICATION

The present application claims the benefit of Korean Patent Application No. 10-2024-0018785, filed on Feb. 7, 2024, which is incorporated herein by reference in its entirety.

### TECHNICAL FIELD

Exemplary embodiments relate to a semiconductor technology, and more particularly, to a semiconductor device having a cross-point structure and a method for fabricating the same.

### BACKGROUND

Recently, with the miniaturization, low power consumption, high performance, diversification, and the like of electronic devices, there is a demand for semiconductor devices capable of storing information in various electronic appliances such as computers and portable communication devices, and research has been conducted for the semiconductor devices. Such semiconductor devices include semiconductor devices capable of storing data by using characteristics that they are switched between different resistance states according to an applied voltage or current, such as a resistive random access memory (RRAM), a phase change random access memory (PRAM), a ferroelectric random access memory (FRAM), a magnetic random access memory (MRAM), and an E-fuse.

### SUMMARY

Various embodiments of the present disclosure are directed to providing a semiconductor device with the degree of improved integration and a method for fabricating the semiconductor device. In the embodiments, a process for fabricating the semiconductor device can be simplified, which makes the fabrication process easy.

A semiconductor device in accordance with an embodiment of the present disclosure may include: a plurality of first conductive lines extending in a first direction; a plurality of second conductive lines disposed over the plurality of first conductive lines and extending in a second direction intersecting the first direction; and a plurality of memory cells overlapping intersection areas between the first conductive lines and the second conductive lines, respectively, wherein the plurality of memory cells may include a plurality of first memory cells each including a first memory pattern and a first selector pattern disposed on the first memory pattern and a plurality of second memory cells each including a second selector pattern and a second memory pattern disposed on the second selector pattern, and in each of the first direction and the second direction, one or more of the first memory cells and one or more of the second memory cells may be alternately arranged.

A method for fabricating a semiconductor device in accordance with an embodiment of the present disclosure may include: forming a plurality of first conductive lines extending in a first direction; forming, on the plurality of first conductive lines, a plurality of memory cells including a plurality of first memory cells each including a first memory pattern and a first selector pattern disposed on the first memory pattern and a plurality of second memory cells each including a second selector pattern and a second memory pattern disposed on the second selector pattern; and forming a plurality of second conductive lines on the plurality of memory cells to extend in a second direction intersecting the first direction, wherein in each of the first direction and the second direction, one or more of the first memory cells and one or more of the second memory cells may be alternately arranged.

In accordance with embodiments of the present disclosure, the degree of integration of a semiconductor device may be improved and a fabricating process may be facilitated.

### BRIEF DESCRIPTION OF THE DRAWINGS

FIG. 1A is an example of a view for illustrating a semiconductor device based on some implementations.

FIG. 1B is a view of a semiconductor device which is taken along a line A1-A1′ in FIG. 1A.

FIG. 1C is a view of a semiconductor device which is taken along a line C1-C1′ in FIG. 1A.

FIG. 1D is a cross-sectional view for illustrating an example of a first memory pattern 120A or a second memory pattern 120B based on some implementations.

FIGS. 2A, 2B, 3A, 3B, 4, 5A, 5B, 6, 7A, 7B, 8A, 8B, 9, 10A, 10B, 11, 12A, and 12B are examples of views for explaining a semiconductor device and a method for fabricating the same in accordance with another embodiment.

### DETAILED DESCRIPTION

Various embodiments are described in detail below with reference to the accompanying drawings.

The drawings may not necessarily be drawn to scale, and in some embodiments, the proportions of at least some of structures illustrated in the drawings may be exaggerated to clearly show features of the embodiments. When a multilayer structure having two or more layers is disclosed in the drawings or detailed description, since the relative positional relationship or arrangement order of the layers illustrated in the drawings merely reflects a specific embodiment, the present disclosure is not limited thereto and the relative positional relationship or arrangement order of the layers may be changed. The drawings or detailed description of the multilayer structure may not reflect all layers existing in a specific multilayer structure (for example, one or more additional layer may exist between two layers illustrated).

For example, when a first layer is located on a second layer or on a substrate in the multilayer structure in the drawings or detailed description, it may not only indicate that the first layer may be directly formed on the second layer or directly formed on the substrate, but also indicate that one or more other layers may exist between the first layer and the second layer, or between the first layer and the substrate.

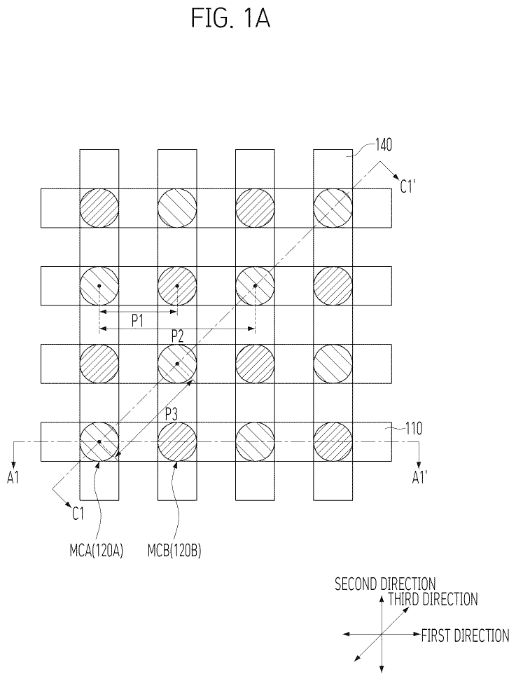

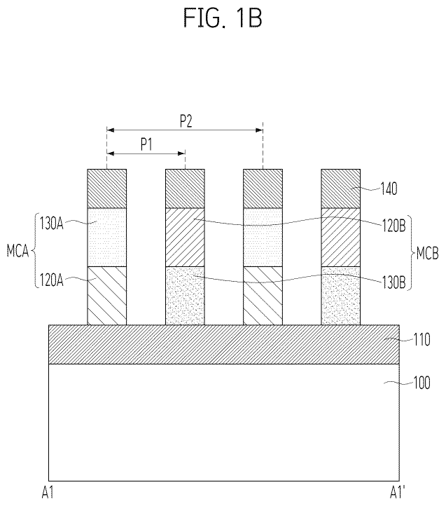

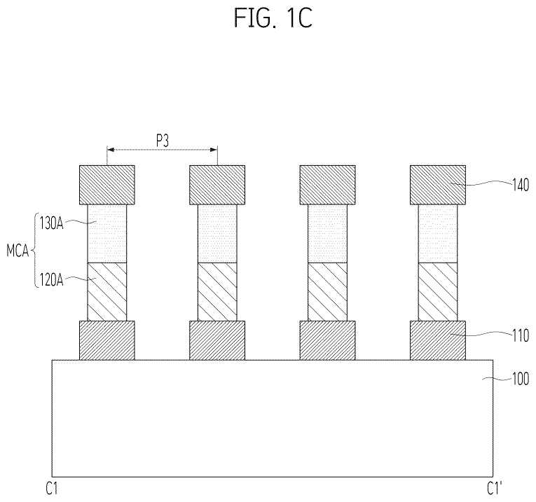

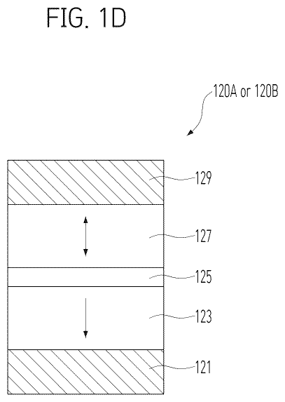

FIGS. 1A to 1C are views for explaining an example of a semiconductor device in accordance with an embodiment of the present disclosure. FIG. 1A is a top view, FIG. 1B is a cross-sectional view taken along line A1-A1′ in FIG. 1A, and FIG. 1C is a cross-sectional view taken along line C1-C1′ in FIG. 1A.

Referring to FIGS. 1A to 1C, the semiconductor device of the present embodiment may include a substrate 100, a plurality of first conductive lines 110 formed on the substrate 100 and extending in a first direction, a plurality of second conductive lines 140 formed separately from and over the first conductive lines 110 and extending in a second direction intersecting the first direction, and a plurality of memory cells MCA and MCB overlapping intersection areas between the first conductive lines 110 and the second conductive lines 140, respectively. In the illustrated example in FIGS. 1B and 1C, memory cells MCA and MCB are located below the second conductive lines 140 and above the first conductive lines 110 and are coupled to the first conductive lines 110 and second conductive lines 140. The first direction and the second direction may correspond to horizontal directions substantially parallel to a top surface of the substrate 100 and may be substantially perpendicular to each other. Compared to the horizontal direction, the direction substantially perpendicular to the top surface of the substrate 100 is referred to as a vertical direction.

The substrate 100 may include a semiconductor material such as silicon. A required predetermined lower structure (not illustrated) may be formed in the substrate 100. For example, a driving circuit for driving the first conductive line 110 and/or the second conductive line 140 may be formed in the substrate 100.

The plurality of first conductive lines 110 may be arranged to be spaced apart from each other in the second direction, and may be located at the same level in the vertical direction. The first conductive line 110 may include various conductive materials, for example, metal such as platinum (Pt), tungsten (W), aluminum (Al), copper (Cu), or tantalum (Ta), metal nitride such as titanium nitride (TiN) or tantalum nitride (TaN), or a combination thereof.

The plurality of second conductive lines 140 may be arranged to be spaced apart from each other in the first direction, and may be located at the same level in the vertical direction. The second conductive line 140 may include various conductive materials, for example, metal such as platinum (Pt), tungsten (W), aluminum (Al), copper (Cu), or tantalum (Ta), metal nitride such as titanium nitride (TIN) or tantalum nitride (TaN), or a combination thereof.

The plurality of memory cells MCA and MCB may include first memory cells MCA and second memory cells MCB. The first memory cell MCA may include a first memory pattern 120A and a first selector pattern 130A on the first memory pattern 120A, and the second memory cell MCB may include a second selector pattern 130B and a second memory pattern 120B on the second selector pattern 130B. In the vertical direction, the first memory pattern 120A and the second selector pattern 130B may be located at substantially the same level, and the second memory pattern 120B and the first selector pattern 130A may be located at substantially the same level. In the implementations, a bottom surface and a top surface of the first memory pattern 120A may be located at substantially the same level as a bottom surface and a top surface of the second selector pattern 130B, respectively, and a bottom surface and a top surface of the second memory pattern 120B may be located at substantially the same level as a bottom surface and a top surface of the first selector pattern 130A, respectively.

One or more first memory cells MCA and one or more second memory cells MCB may be alternately arranged along each of the first direction and the second direction. The present embodiment describes a case in which two first memory cells MCA and two second memory cells MCB are alternately arranged in each of the first direction and the second direction; however, the present disclosure is not limited thereto and the number of first memory cells MCA and the number of second memory cells MCB may be variously changed. In a third direction intersecting the first direction and the second direction, the plurality of first memory cells MCA may be arranged in a row, and the plurality of second memory cells MCB may be arranged in a row. The third direction may be in a same plane as the horizontal direction, and may correspond to a diagonal direction, for example, a direction forming about 45° with respect to each of the first direction and the second direction. When a distance between the centers of the first memory cell MCA and the second memory cell MCB, which are adjacent to each other in the first direction, is referred to as a first distance P1 and a distance between the centers of two first memory cells MCA, which are adjacent to each other in the first direction, is referred to as a second distance P2, the second distance P2 may be larger than the first distance P1. For example, the second distance P2 may be approximately twice the first distance P1. Although not illustrated, a distance between the centers of two second memory cells MCB, which are adjacent to each other in the first direction, may be substantially equal to the second distance P2. Although not illustrated, a distance between the centers of the first memory cell MCA and the second memory cell MCB, which are adjacent to each other in the second direction, may be substantially equal to the first distance P1, and a distance between the centers of two first memory cells MCA, which are adjacent to each other in the second direction, and a distance between the centers of two second memory cells MCB, which are adjacent to each other in the second direction, may be substantially equal to the second distance P2, respectively. When a distance between the centers of two first memory cells MCA, which are adjacent to each other in the third direction, is referred to as a third distance P3, the third distance P3 may be larger than the first distance P1 and may be smaller than the second distance P2. For example, the third distance P3 may correspond to approximately v2 times the first distance P1. Although not illustrated, a distance between the centers of two second memory cells MCB, which are adjacent in the third direction, may be substantially equal to the third distance P3.

The first memory pattern 120A and the second memory pattern 120B may be parts of the first memory cell MCA and the second memory cell MCB that store data, respectively. As an example, each of the first memory pattern 120A and the second memory pattern 120B may correspond to a variable resistance element that stores different data by switching between different resistance states. For example, each of the first memory pattern 120A and the second memory pattern 120B may have a single-layer structure or a multilayer structure including various materials used in RRAM, PRAM, FRAM, MRAM, or others, for example, transition metal oxides, metal oxides such as perovskite-based materials, phase change materials such as chalcogenide-based materials, ferroelectric materials, ferromagnetic materials, or others. In the drawings, different hatchings are used to distinguish the first memory pattern 120A and the second memory pattern 120B; however, the first memory pattern 120A and the second memory pattern 120B may be substantially the same. For example, each of the first memory pattern 120A and the second memory pattern 120B may include the same magnetic tunnel junction structure. This is described in more detail with reference to FIG. 1D.

FIG. 1D is a cross-sectional view for illustrating an example of the first memory pattern 120A or the second memory pattern 120B. Thus, the example as shown in FIG. 1D can be applied to at least one of the first memory pattern 120A or the second memory pattern 120B. Referring to FIG. 1D, the first memory pattern 120A or the second memory pattern 120B may include a magnetic tunnel junction structure having a stacked structure of a first electrode layer 121, a fixed layer 123, a tunnel barrier layer 125, a free layer 127, and a second electrode layer 129.

The fixed layer 123 is a layer that may be compared with the magnetization direction of the free layer 127 by having a fixed magnetization direction, and may also be referred to as a reference layer or the like. The free layer 127 is a layer that may store different data by having a changeable magnetization direction, and may also be referred to a storage layer or the like. In the present embodiment, the fixed layer 123 and the free layer 127 may have magnetization directions substantially perpendicular to the surfaces of the layers, the magnetization direction of the fixed layer 123 may be fixed in a top-down direction, and the magnetization direction of the free layer 127 may be varied between a top-down direction and a bottom-up direction.

However, the present disclosure is not limited thereto. In another embodiment, the magnetization direction of the fixed layer 123 may be fixed in a bottom-up direction. Alternatively, in another embodiment, the fixed layer 123 and the free layer 127 may have magnetization directions substantially parallel to the surfaces of the layers. The tunnel barrier layer 125 may be interposed between the fixed layer 123 and the free layer 127 to physically separate the fixed layer 123 and the free layer 127, and enable tunneling of electrons between the fixed layer 123 and the free layer 127 depending on a voltage or a current applied to the magnetic tunnel junction structure. The fixed layer 123 and the free layer 127 may each have a single-layer structure or a multilayer structure including a ferromagnetic material. As an example, each of the fixed layer 123 and the free layer 127 may include an alloy containing Fe, Ni, or Co as a main component, for example, at least one of a Fe—Pt alloy, a Fe—Pd alloy, a Co—Pd alloy, a Co—Pt alloy, a Fe—Ni—Pt alloy, a Co—Fe—Pt alloy, a Co—Ni—Pt alloy, or a Co—Fe—B alloy, or may include at least one of a Co/Pt stacked structure or a Co/Pd stacked structure. The tunnel barrier layer 125 may have a single-layer structure or a multilayer structure including an insulating material. In an example, the tunnel barrier layer 125 may include insulating oxide such as MgO, CaO, SrO, TiO, VO, or NbO.

Each of the first electrode layer 121 and the second electrode layer 129 is configured for transmitting a voltage or a current, and may include various conductive materials, for example, metal such as platinum (Pt), tungsten (W), aluminum (Al), copper (Cu), or tantalum (Ta), metal nitride such as titanium nitride (TiN) or tantalum nitride (TaN), or a combination thereof. Each of the first electrode layer 121 and the second electrode layer 129 may, as needed, perform a function of assisting in a formation process of the magnetic tunnel junction structure or improving the characteristics of the magnetic tunnel junction structure, and accordingly, may also be referred to as a capping layer, a hard mask layer, a lower layer, a seed layer, or others.

Such a magnetic tunnel junction structure may store different data by switching between different resistance states depending on a voltage or a current applied through a top end and a bottom end thereof. More specifically, when the magnetization direction of the free layer 127 varies depending on a voltage or a current applied to the magnetic tunnel junction structure and is parallel to the magnetization direction of the fixed layer 123, the magnetic tunnel junction structure may have a low resistance state, for example, may store data ‘1’. On the other hand, when the magnetization direction of the free layer 127 varies depending on a voltage or a current applied to the magnetic tunnel junction structure and is antiparallel to the magnetization direction of the fixed layer 123, the magnetic tunnel junction structure may have a high resistance state, for example, may store data ‘0’. In some other implementations, the magnetic tunnel junction structure may store data ‘1’ when magnetic tunnel junction structure has a high resistance state and the magnetic tunnel junction structure may store data ‘0’ when the magnetic tunnel junction structure has a low resistance state.

As long as the magnetic tunnel junction structure includes the fixed layer 123, the free layer 127, and the tunnel barrier layer 125 interposed between the fixed layer 123 and the free layer 127, the layer structure of the magnetic tunnel junction structure may be variously modified. In an example, the magnetic tunnel junction structure may further include one or more layers for improving characteristics of the magnetic tunnel junction structure. Alternatively, in an example, at least one of the first electrode layer 121 and the second electrode layer 129 may be omitted. Alternatively, in an example, the positions of the fixed layer 123 and the free layer 127 may be reversed.

Returning back to FIGS. 1A to 1C, the first selector pattern 130A may serve to substantially prevent or reduce a current leakage that may occur between the first memory cells MCA sharing the first conductive line 110 or the second conductive line 140 while controlling access to the first memory pattern 120A. The second selector pattern 130B may serve to substantially prevent or reduce a current leakage that may occur between the second memory cells MCB sharing the first conductive line 110 or the second conductive line 140 while controlling access to the second memory pattern 120B. In the implementations, each of the first selector pattern 130A and the second selector pattern 130B may have threshold switching characteristics to selectively switch between two electrical conducting states: (1) an electrical non-conducting state that blocks a current to flow through, or allows almost no current to flow through, when a voltage supplied to its top and bottom ends is less than a predetermined threshold voltage, and (2) an electrical conducting state that allows a current to rapidly flow through when the supplied voltage is above the predetermined threshold voltage. Thus, each of the first selector pattern 130A and the second selector pattern 130B may be turned on above the threshold voltage and turned off below the threshold voltage.

Each of the first selector pattern 130A and the second selector pattern 130B may include an ovonic threshold switching (OTS) material such as a diode or a chalcogenide-based material, a mixed ionic electronic conducting (MIEC) material such as a metal-containing chalcogenide-based material, a metal insulator transition (MIT) material such as NbO₂ or VO₂, a tunneling insulating material with a relatively wide band gap such as SiO₂, Al₂O₃, or others.

Alternatively, each of the first selector pattern 130A and the second selector pattern 130B may include an insulating material containing a dopant implanted through a method such as ion implantation. The insulating material may include a silicon-containing insulating material such as silicon oxide, silicon nitride, silicon oxynitride, insulating metal oxide, insulating metal nitride, or a combination thereof. The dopant may generate a trap site for capturing conductive carriers moving within an insulating material or providing a passage through which the trapped conductive carriers move again. In order to form such a trap site, various elements that generate an energy level capable of accommodating conductive carriers within the insulating material may be used as a dopant. As an example, when the insulating material includes a silicon-containing insulating material, the dopant may include a metal with a different valence than silicon, such as aluminum (Al), lanthanum (La), niobium (Nb), vanadium (V), tantalum (Ta), tungsten (W), chromium (Cr), molybdenum (Mo), gallium (Ga), boron (B), indium (In), phosphorus (P), arsenic (As), antimony (Sb), germanium (Ge), carbon (C), or a combination thereof. Alternatively, when the insulating material includes insulating metal oxide or insulating metal nitride, the dopant may include a metal having a different valence from the metal of the metal oxide or the metal nitride, silicon, or others. In an example, the first selector pattern 130A or the second selector pattern 130B may include silicon dioxide (SiO₂) doped with arsenic (As). When a voltage above the threshold voltage is applied to the first selector pattern 130A or the second selector pattern 130B, the conductive carriers move through the trap site, thereby implementing an on state in which current flows through the first selector pattern 130A or the second selector pattern 130B. When the voltage applied to the first selector pattern 130A or the second selector pattern 130B is reduced below the threshold voltage, no conductive carriers move, thereby implementing an off state in which no current flows.

In the drawings, different hatchings are used to distinguish the first selector pattern 130A and the second selector pattern 130B; however, in some implementations, the first selector pattern 130A and the second selector pattern 130B may be substantially identical to each other. For example, each of the first selector pattern 130A and the second selector pattern 130B may include silicon dioxide doped with arsenic, and the arsenic concentration of the first selector pattern 130A and the arsenic concentration of the second selector pattern 130B may be substantially identical to each other.

Each of the first memory cell MCA and the second memory cell MCB may have a pillar shape overlapping the intersection area of the first conductive line 110 and the second conductive line 120. In addition, each of the first memory pattern 120A and the first selector pattern 130A of the first memory cell MCA may have a pillar shape, and the second memory pattern 120B and the second selector pattern 130B of the second memory cell MCB may have a pillar shape. The present embodiment describes the case in which the first memory pattern 120A and the first selector pattern 130A form the first memory cell MCA having a cylindrical shape with sidewalls aligned with each other, and the second memory pattern 120B and the second selector pattern 130B form the second memory cell MCB having a cylindrical shape with sidewalls aligned with each other; however, the present disclosure is not limited thereto. In another example, while the first memory pattern 120A and the first selector pattern 130A have sidewalls aligned with each other, the pillar shape of the first memory cell MCA may be variously modified into an elliptical pillar, a square pillar, or others. While the second memory pattern 120B and the second selector pattern 130B have sidewalls aligned with each other, the pillar shape of the second memory cell MCB can be variously modified into an elliptical pillar, a square pillar, or the like. The pillar shape of the first memory cell MCA and the pillar shape of the second memory cell MCB may be identical to each other. Alternatively, in another example, the first memory pattern 120A and the first selector pattern 130A may have different pillar shapes while their sidewalls are not aligned with each other, and the second memory pattern 120B and the second selector pattern 130A may have different pillar shapes while their sidewalls are not aligned with each other. In some implementations, the pillar shape of the first memory pattern 120A and the pillar shape of the second memory pattern 120B may be identical to each other. In some other implementations, the pillar shape of the first selector pattern 130A and the pillar shape of the second selector pattern 130B may be identical to each other.

According to the semiconductor device described above, various advantages may be acquired compared to a semiconductor device of a comparative example.

In the semiconductor device of the comparative example, all memory cells may have the same layer structure. For example, all the memory cells in the semiconductor device of the comparative example may have a structure in which a selector pattern is located on a memory pattern, similar to the above-described first memory cell MCA. Alternatively, for example, all the memory cells in the semiconductor device of the comparative example may have a structure in which the memory pattern is located on the selector pattern, similar to the above-described second memory cell MCB. Accordingly, all memory patterns may be located at the same level in the vertical direction. In such a case, the pitch of the memory cell in the comparative example, that is, a distance between the centers of two adjacent memory cells, may be the same as the pitch of the memory pattern. In order to achieve high integration of the semiconductor device, the pitch of the memory cell needs to be essentially reduced. However, in a case in which the memory pattern is located at the same level in the vertical direction, when the pitch of the memory cell is decreased, the pitch of the memory pattern may also be decreased. When the pitch of the memory pattern is decreased, the degree of difficulty of an etching process for forming the memory pattern may be increased. For example, when the memory pattern includes a magnetic tunnel junction structure, difficulties such as a decrease in an etchable angle may occur during an ion bean etching (IBE) process used to etch the magnetic tunnel junction structure.

In the present embodiment, since the first memory cell MCA and the second memory cell MCB have an inverted layer structure, the first memory pattern 120A and the second memory pattern 120B may be located at different levels in the vertical direction. In such a case, compared to the semiconductor device of the comparative example, the pitch of the first memory pattern 120A and the pitch of the second memory pattern 120B may be greatly increased under the same area. For example, when the pitch of the memory pattern in the semiconductor device of the comparative example corresponds to the first distance P1, the pitch of the first memory pattern 120A may correspond to the second distance P2 and the pitch of the memory pattern 120B may correspond to the second distance P2 in the semiconductor device of the present embodiment. As a result, the degree of difficulty of an etching process for forming the first memory pattern 120A and the second memory pattern 120B may be reduced. For example, when each of the first memory pattern 120A and the second memory pattern 120B includes a magnetic tunnel junction structure, an etchable angle may be increased during an IBE process for forming the first memory pattern 120A and the second memory pattern 120B.

In the present embodiment, the second selector pattern 130B may be located between two first memory patterns 120A adjacent in each of the first direction and the second direction, and the first selector pattern 130A may be located between two adjacent second memory patterns 120B. In such a case, when the first and second selector patterns 130A and 130B are formed using a fabricating method to be described below, the process may be facilitated and damage to the first and second selector patterns 130A and 130B due to etching may be substantially prevented.

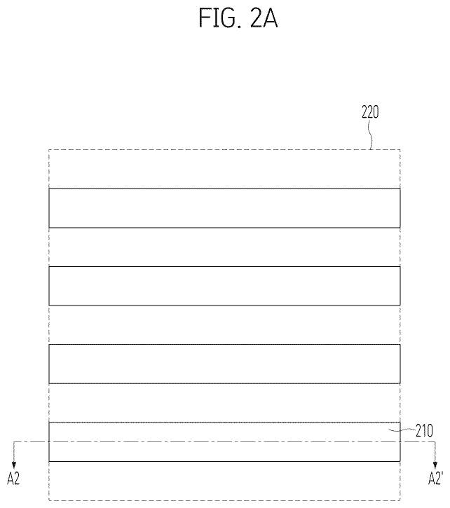

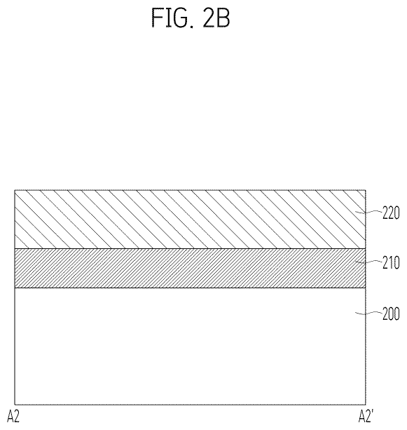

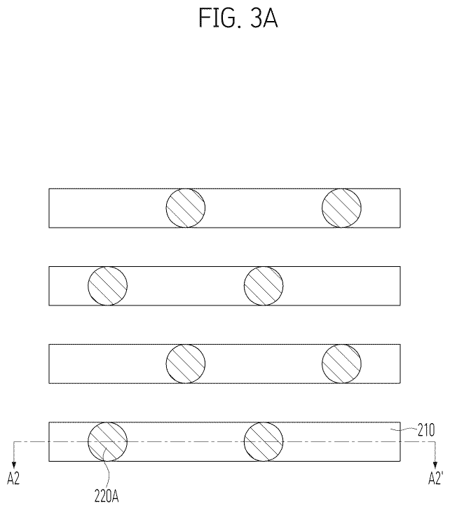

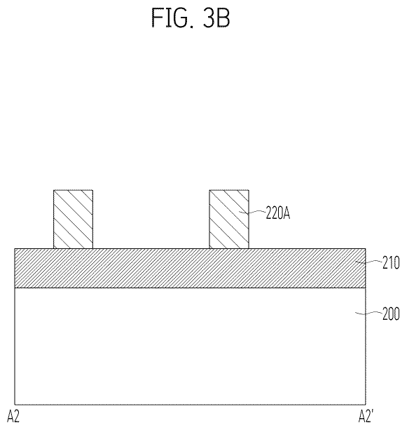

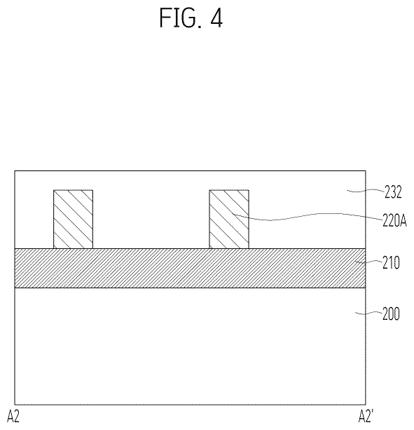

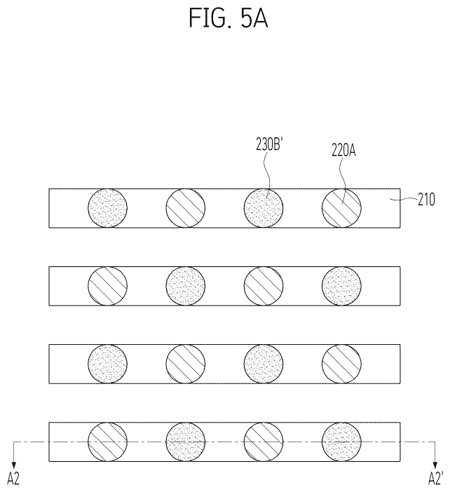

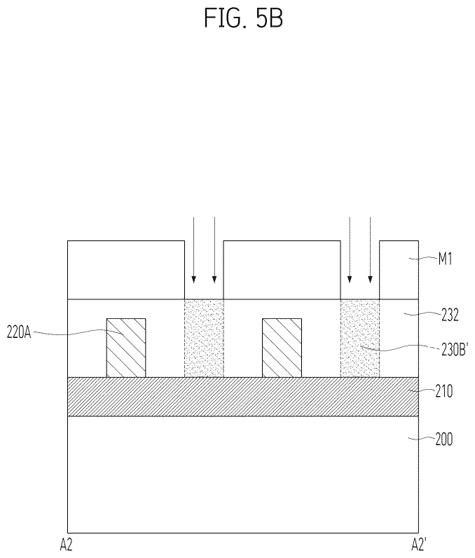

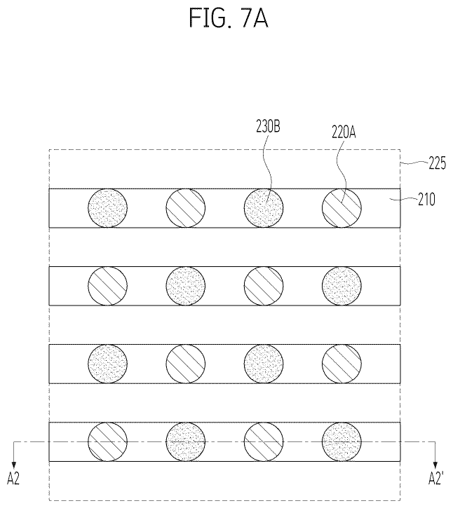

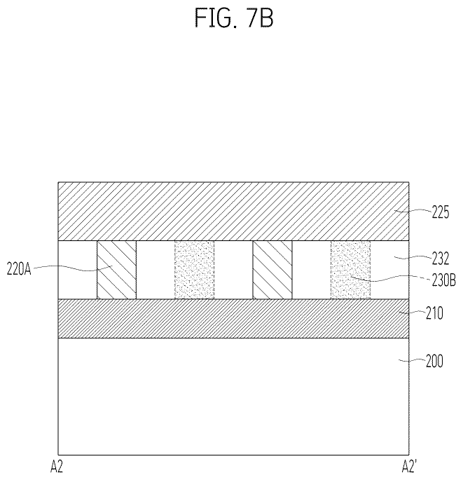

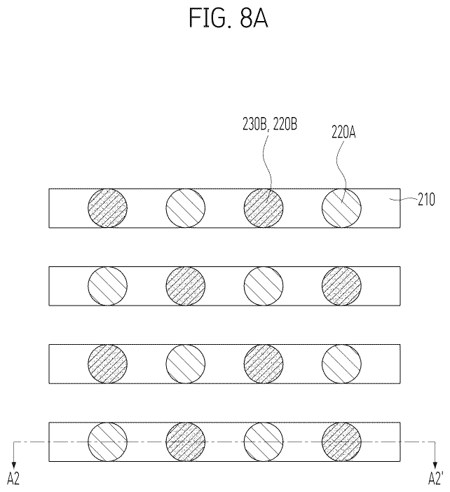

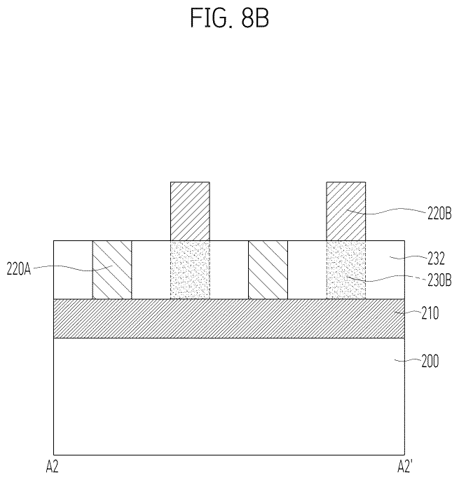

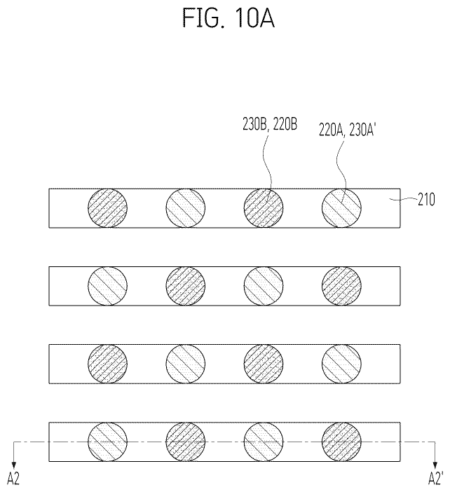

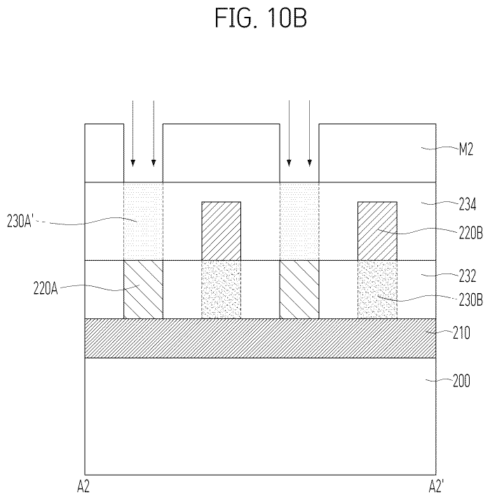

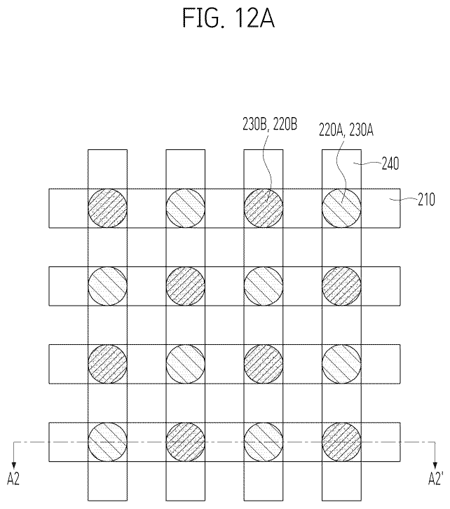

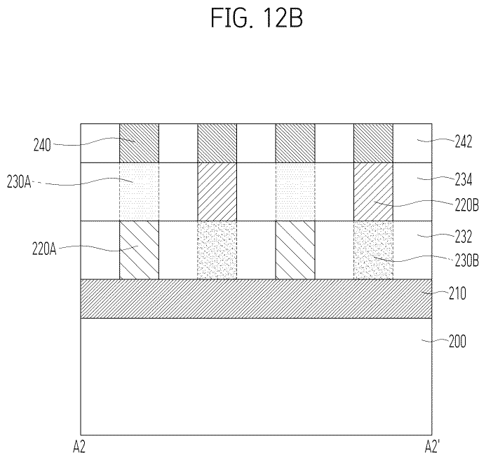

FIGS. 2A, 2B, 3A, 3B, 4, 5A, 5B, 6, 7A, 7B, 8A, 8B, 9, 10A, 10B, 11, 12A, and 12B are views for explaining a semiconductor device and a method for fabricating the same in accordance with another embodiment of the present disclosure. FIGS. 2A, 3A, 5A, 7A, 8A, 10A, 12A are top views. FIGS. 2B, 3B, 5B, 7B, 8B, 10B, and 12B are cross-sectional views taken along line A2-A2′ of FIGS. 2A, 3A, 5A, 7A, 8A, 10A, and 12A, respectively. FIGS. 4, 6, 9, and 11 are cross-sectional views for explaining a process between FIGS. 3B and 5B, a process between FIGS. 5B and 7B, a process between FIGS. 8B and 10B, and a process between FIGS. 10B and 12B, respectively. Detailed description of parts that are substantially the same as the above-described embodiment is omitted.

First, the fabricating method is described.

Referring to FIGS. 2A and 2B, the plurality of first conductive lines 210 extending in the first direction may be formed on the substrate 200. The first conductive line 210 may be formed by depositing a conductive material on the substrate 200 and selectively etching the conductive material. Subsequently, although not illustrated, an interlayer dielectric layer may be formed to fill a space between the first conductive lines 210. The interlayer dielectric layer may be formed by depositing, on the substrate 200, an insulating material with a thickness for sufficiently covering the first conductive line 210 and then performing a planarization process, such as chemical mechanical polishing (CMP) or etch-back, until a top surface of the first conductive line 210 is exposed.

Subsequently, a first memory layer 220 may be formed on the first conductive line 210 and the interlayer dielectric layer between the first conductive lines 210. In a plan view, the first memory layer 220 may have a flat shape covering the substrate 200. The first memory layer 220 is used to form a first memory pattern to be described below, and may have a multilayer structure. For example, the first memory layer 220 may have a multilayer structure of forming a magnetic tunnel junction structure. The first memory layer 220 may be formed by sequentially depositing layers for forming a multilayer structure.

Referring to FIGS. 3A and 3B, after a mask pattern (not illustrated) covering an area where the first memory pattern is to be formed is formed on the first memory layer 220, a plurality of first memory patterns 220A may be formed by etching the first memory layer 220 using the mask pattern as an etch barrier. The etching process for the first memory layer 220 may be performed, for example, using an IBE method.

The plurality of first memory patterns 220A may have the same shape and arrangement as the first memory pattern (see 120A of FIGS. 1A to 1C) of the above-described embodiment. In the implementations, the first memory pattern 220A may have a pillar shape. The plurality of first memory patterns 220A may be arranged on the first conductive line 210 to overlap the first conductive line 210, may be arranged to have a pitch corresponding to a second distance (see P2 in FIGS. 1A and 1B) in each of the first direction and the second direction, and may be arranged to have a pitch corresponding to a third distance (see P3 in FIGS. 1A and 1C) in the third direction. In such a case, since the pitch of the plurality of first memory patterns 220A is relatively large, an etching process for the first memory layer 220, such as an IBE process, may be performed relatively easily.

Referring to FIG. 4, a first insulating layer 232 may be formed to cover the process results of FIGS. 3A and 3B. The first insulating layer 232 may cover the sidewalls and the top surface of the first memory pattern 220A, thereby having a top surface of the first insulating layer 232 located above the top surface of the first memory pattern 220A. The first insulating layer 232 may be formed by depositing an insulating material. After the deposition of the insulating material, the first insulating layer 232 having a planarized top surface may be formed through a planarization process.

The first insulating layer 232 may be used as a matrix for forming a first selector pattern which is to be described below. The first insulating layer 232 may include various insulating materials, such as silicon-containing insulating materials such as silicon oxide, silicon nitride, or silicon oxynitride, insulating metal oxide, insulating metal nitride, or a combination thereof. In an example, the first insulating layer 232 may include silicon dioxide.

Referring to FIGS. 5A and 5B, after a first mask pattern M1 exposing an area where a second selector pattern is be formed is formed on the first insulating layer 232, a plurality of initial second selector patterns 230B′ may be formed by doping a dopant into a part of the first insulating layer 232 exposed by the first mask pattern M1. The dopant may be doped by an ion implantation method (see arrows). The dopant may serve to generate a trap site for providing a movement path for conductive carriers within the first insulating layer 232. When the first insulating layer 232 includes a silicon-containing insulating material, the dopant may include a metal with a different valence than silicon, such as aluminum (Al), lanthanum (La), niobium (Nb), vanadium (V), tantalum (Ta), tungsten (W), chromium (Cr), molybdenum (Mo), gallium (Ga), boron (B), indium (In), phosphorus (P), arsenic (As), antimony (Sb), germanium (Ge), carbon (C), or a combination thereof. Alternatively, when the first insulating layer 232 includes insulating metal oxide or insulating metal nitride, the dopant may include a metal having a different valence from the metal of the metal oxide or the metal nitride, silicon, or others. When the first insulating layer 232 includes silicon dioxide, the dopant may include arsenic. Accordingly, the initial second selector pattern 230B′ may include silicon dioxide doped with arsenic. The remainder of the first insulating layer 232 not exposed by the first mask pattern M1 may be maintained as is.

The plurality of initial second selector patterns 230B′ may have the same arrangement as the second selector pattern (see 130B in FIG. 1B) of the above-described embodiment. Thus, the plurality of second initial selector patterns 230B″ may be arranged on the first conductive line 210 to overlap the first conductive line 210, may be arranged to have a pitch corresponding to the second distance (see P2 in FIGS. 1A and 1B) in each of the first direction and the second direction, and may be arranged to have a pitch corresponding to the third distance (see P3 in FIGS. 1A and 1C) in the third direction. In addition, the plurality of second initial selector patterns 230B′ may be alternately arranged with the plurality of first memory patterns 220A in each of the first direction and the second direction. However, a top surface of the initial second selector pattern 230B′ may be located above a top surface of the first memory pattern 220A or a top surface of the second selector pattern (see 130B in FIG. 1B) of the above-described embodiment.

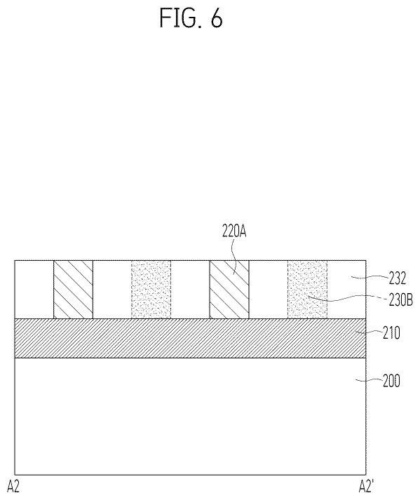

Referring to FIG. 6, a planarization process, such as CMP or etch-back, may be performed until the top surface of the first memory pattern 220A is exposed. As a result of this process, a second selector pattern 230B having a top surface located at substantially the same level as the top surface of the first memory pattern 220A may be formed. In this process, the top surface of the first insulating layer 232 is also lowered to form a planarized surface in which the top surface of the first memory pattern 220A, the top surface of the second selector pattern 230B, and the top surface of the first insulating layer 232 are located at the same level.

When the second selector pattern 230B is formed in this manner, a simple and easy process can be performed without damaging the previously formed first memory pattern 220A.

Referring to FIGS. 7A and 7B, a second memory layer 225 may be formed on the process result of FIG. 6. In the plan view, the second memory layer 225 may have a flat shape covering the substrate 200. The second memory layer 225 may be used to form a second memory pattern which is to be described below, and may have a multilayer structure. For example, the multilayer structure of the second memory layer 255 may form a magnetic tunnel junction structure. The second memory layer 225 may be the same as the first memory layer 220 and may be formed in the same manner as the process of forming the first memory layer 220.

Referring to FIGS. 8A and 8B, after a mask pattern (not illustrated) covering an area where the second memory pattern is to be formed is formed on the second memory layer 225, a plurality of second memory patterns 220B may be formed by etching the second memory layer 225 using the mask pattern as an etch barrier. The etching process for the second memory layer 225 may be performed, for example, using an IBE method.

The plurality of second memory patterns 220B may have the same shape and arrangement as the second memory pattern (see 120B in FIGS. 1A and 1B) in the above-described embodiment. In such a case, since the pitch of the plurality of second memory patterns 220B is relatively large, an etching process of the second memory layer 225, such as an IBE process, may be relatively facilitated. The plurality of second memory patterns 220B may be formed on the plurality of second selector patterns 230B to overlap the plurality of second selector patterns 230B, respectively. To this end, a mask pattern (not illustrated) for forming the plurality of second memory patterns 220B may have a shape covering the part exposed by the first mask pattern (see M1 in FIG. 5B) and exposing the part covered by the first mask pattern.

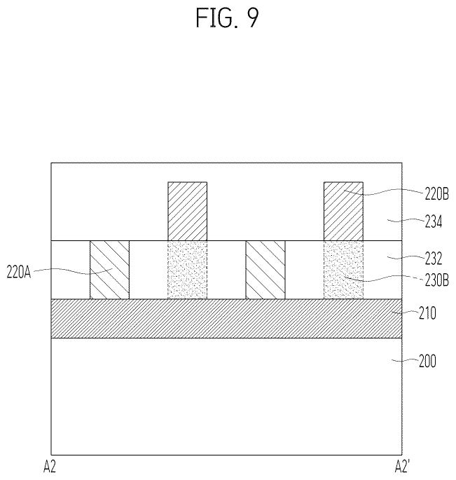

Referring to FIG. 9, a second insulating layer 234 may be formed to cover the process results of FIGS. 8A and 8B.

The second insulating layer 234 may be used as a matrix for forming a second selector pattern to be described below. The second insulating layer 234 may include various insulating materials, such as silicon-containing insulating materials such as silicon oxide, silicon nitride, or silicon oxynitride, insulating metal oxide, insulating metal nitride, or a combination thereof. In an example, the second insulating layer 234 may include silicon dioxide. The second insulating layer 234 may include the same insulating material as the first insulating layer 232.

Referring to FIGS. 10A and 10B, after a second mask pattern M2 exposing an area where the first selector pattern is be formed is formed on the second insulating layer 234, a plurality of initial first selector patterns 230A′ may be formed by doping a dopant into a part of the second insulating layer 234 exposed by the second mask pattern M2. The dopant may be doped by an ion implantation method (see arrows). In addition, various process conditions for forming the initial first selector pattern 230A′, such as dopant concentration and ion implantation energy, may be substantially the same as various process conditions for forming the initial second selector pattern 230B′, such as dopant concentration and ion implantation energy. The dopant may serve to generate a trap site for providing a movement path for conductive carriers within the second insulating layer 234. When the second insulating layer 234 includes a silicon-containing insulating material, the dopant may include a metal with a different valence than silicon, such as aluminum (Al), lanthanum (La), niobium (Nb), vanadium (V), tantalum (Ta), tungsten (W), chromium (Cr), molybdenum (Mo), gallium (Ga), boron (B), indium (In), phosphorus (P), arsenic (As), antimony (Sb), germanium (Ge), carbon (C), or a combination thereof. Alternatively, when the second insulating layer 234 includes insulating metal oxide or insulating metal nitride, the dopant may include a metal having a different valence from the metal of the metal oxide or the metal nitride, silicon, or others. When the second insulating layer 234 includes silicon dioxide, the dopant may include arsenic. Accordingly, the initial first selector pattern 230A′ may include silicon dioxide doped with arsenic. The remainder of the second insulating layer 234 not exposed by the second mask pattern M2 may be maintained as is.

The plurality of initial first selector patterns 230A′ may have the same arrangement as the first selector pattern (see 130A of FIGS. 1B and 1C) of the above-described embodiment. The plurality of initial first selector patterns 230A′ may be formed on the plurality of first memory patterns 220A to overlap the plurality of first memory patterns 220A, respectively. In some implementations, the second mask pattern M2 may have a shape covering the part exposed by the mask pattern (not illustrated) for forming the plurality of first memory patterns 220A and exposing the part covered by the mask pattern.

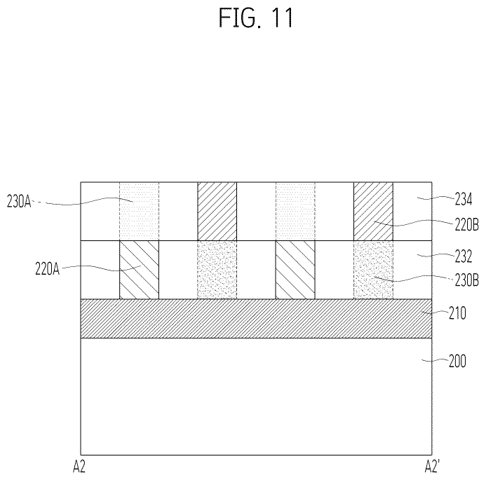

Referring to FIG. 11, a planarization process, such as CMP or etch-back, may be performed until the top surface of the second memory pattern 220B is exposed. As a result of this process, the first selector pattern 230A having a top surface located at substantially the same level as the top surface of the second memory pattern 220B may be formed. In this process, the top surface of the second insulating layer 234 is also lowered to form a planarized surface in which the top surface of the second memory pattern 220B, the top surface of the first selector pattern 230A, and the top surface of the second insulating layer 234 are located at the same level.

Referring to FIGS. 12A and 12B, a plurality of second conductive lines 240 extending in the second direction may be formed on the process result of FIG. 11. The second conductive line 240 may be formed by depositing a conductive material on the process result of FIG. 11 and selectively etching the conductive material.

Subsequently, an interlayer dielectric layer 242 may be formed to fill a space between the second conductive lines 240. The interlayer dielectric layer 242 may be formed by depositing, on the process result of FIG. 11, an insulating material with a thickness for sufficiently covering the second conductive line 240 and then performing a planarization process until a top surface of the second conductive line 240 is exposed.

By the process described above, the semiconductor device illustrated in FIGS. 12A and 12B may be fabricated.

Referring back to FIGS. 12A and 12B, the semiconductor device of the present embodiment may include the plurality of first conductive lines 210 extending in the first direction, the plurality of second conductive lines 240 disposed separately from and over the first conductive lines 210 and extending in the second direction, a stacked structure of the first memory patterns 220A and the first selector patterns 230A overlapping the intersection areas between the first conductive lines 210 and the second conductive lines 240, respectively, and a stacked structure of the second selector patterns 230B and the second memory patterns 220B. In the example in FIGS. 12A and 12B, the first memory patterns 220A and the first selector patterns 230A form first memory cells, and the second selector patterns 230B and the second memory patterns 220B form second memory cells. The first memory cells and the second memory cells may be alternately arranged in each of the first direction and the second direction. The plurality of first memory cells may be arranged in a row in the third direction, and the plurality of second memory cells may be arranged in a row in the third direction.

Each of the first selector pattern 230A and the second selector pattern 230B may include an insulating material and a dopant doped into the insulating material. The insulating material of the first selector pattern 230A may be the same as the second insulating layer 234, and the insulating material of the second selector pattern 230B may be the same as the first insulating layer 232.

Since more detailed description of the components of the semiconductor device of the present embodiment has already been described in the fabricating method, the description is omitted.

Although examples of embodiments of the present disclosure are described above, variations of the disclosed examples of embodiments and various other embodiments can be made based on the present disclosure.

What is claimed is:

1. A semiconductor device comprising:
a plurality of first conductive lines extending in a first direction;
a plurality of second conductive lines disposed separately from and over the plurality of first conductive lines and extending in a second direction intersecting the first direction; and
a plurality of memory cells respectively overlapping intersection areas between the plurality of first conductive lines and the plurality of second conductive lines,
wherein the plurality of memory cells includes a plurality of first memory cells each including a first memory pattern and a first selector pattern disposed on the first memory pattern and a plurality of second memory cells each including a second selector pattern and a second memory pattern disposed on the second selector pattern, each of the first memory pattern and the second memory pattern configured to store data and each of the first selector pattern and the second selector pattern configured to exhibit different electrical conducting characteristics in response to an applied voltage with respect to a threshold voltage, and
wherein one of the plurality of first memory cells and one of the plurality of second memory cells are alternately arranged in each of the first direction and the second direction.

2. The semiconductor device of claim 1, wherein the plurality of first memory cells are arranged in a row in a third direction intersecting the first direction and the second direction.

3. The semiconductor device of claim 2, wherein a distance between centers of two first memory cells that are adjacent in the first direction or the second direction is larger than a distance between centers of two first memory cells that are adjacent in the third direction.

4. The semiconductor device of claim 1, wherein the plurality of second memory cells are arranged in a row in a third direction intersecting the first direction and the second direction.

5. The semiconductor device of claim 4, wherein a distance between centers of two second memory cells that are adjacent in the first direction or the second direction is larger than a distance between centers of two second memory cells that are adjacent in the third direction.

6. The semiconductor device of claim 1, wherein the first memory pattern and the second selector pattern are located at a first level in a vertical direction, and
the second memory pattern and the first selector pattern are located at a second level in the vertical direction.

7. The semiconductor device of claim 1, wherein at least one of the first memory pattern and the second memory pattern includes a magnetic tunnel junction structure.

8. The semiconductor device of claim 1, wherein at least one of the first selector pattern and the second selector pattern includes an insulating material and a dopant doped into the insulating material, and
the dopant is configured to generate a trap site for providing a movement path for conductive carriers in the insulating material.

9. The semiconductor device of claim 1, further comprising:
a first insulating layer filling a space between the first memory pattern and the second selector pattern and including an insulating material,
wherein the second selector pattern includes the insulating material and a dopant doped into the insulating material.

10. The semiconductor device of claim 1, further comprising:
a second insulating layer filling a space between the second memory pattern and the first selector pattern,
wherein the first selector pattern includes a same insulating material as the second insulating layer and a dopant doped into the insulating material.

11. The semiconductor device of claim 1, wherein the first memory pattern and the second memory pattern are identical to each other.

12. The semiconductor device of claim 1, wherein the first selector pattern and the second selector pattern are identical to each other.

13. The semiconductor device of claim 1, further comprising:
a first insulating layer filling a space between the first memory pattern and the second selector pattern;
a second insulating layer filling a space between the second memory pattern and the first selector pattern,
wherein the first insulating layer and the second insulating layer are identical to each other.

14. A method for fabricating a semiconductor device, comprising:
forming a plurality of first conductive lines extending in a first direction;
forming, over the plurality of first conductive lines, a plurality of memory cells including a plurality of first memory cells each including a first memory pattern and a first selector pattern disposed on the first memory pattern and a plurality of second memory cells each including a second selector pattern and a second memory pattern disposed on the second selector pattern, each of the first memory pattern and the second memory pattern configured to store data and each of the first selector pattern and the second selector pattern configured to exhibit different electrical conducting characteristics in response to an applied voltage with respect to a threshold voltage; and
forming a plurality of second conductive lines over the plurality of memory cells to extend in a second direction intersecting the first direction so that the plurality of memory cells is coupled between the plurality of first conductive lines and the plurality of second conductive lines,
wherein one of the plurality of first memory cells and one of the plurality of second memory cells are alternately arranged in each of the first direction and the second direction.

15. The method of claim 14, wherein the forming of the plurality of memory cells comprises:
forming the first memory pattern and the second selector pattern on a first conductive line; and
forming the first selector pattern and the second memory pattern on the first memory pattern and the second selector pattern, respectively.

16. The method of claim 15, wherein the forming of the second selector pattern comprises:
forming a first insulating layer covering the first memory pattern;
forming a first mask pattern on the first insulating layer to expose an area for forming the second selector pattern;
doping a dopant for generating a trap site into a part of the first insulating layer exposed by the first mask pattern, the trap site providing a movement path of conductive carriers in the first insulating layer; and
performing a planarization process to expose a top surface of the first memory pattern.

17. The method of claim 15, wherein the forming of the first selector pattern comprises:
forming a second insulating layer covering the second memory pattern;
forming a second mask pattern on the second insulating layer to expose an area for forming the first selector pattern;
doping a dopant for generating a trap site into a part of the second insulating layer exposed by the second mask pattern, the trap site providing a movement path of conductive carriers in the second insulating layer; and
performing a planarization process to expose a top surface of the second memory pattern.

18. The method of claim 15, wherein the forming of the first memory pattern or the forming of the second memory pattern comprises:
forming a memory layer; and
selectively etching the memory layer.

19. The method of claim 18, wherein the memory layer includes a magnetic tunnel junction structure, and
the etching of the memory layer includes performing an ion beam etching (IBE) method.

20. The method of claim 14, wherein the plurality of first memory cells is arranged in a row in a third direction intersecting the first direction and the second direction, and
the plurality of second memory cells is arranged in a row in the third direction.
